(19) United States
(12) Patent Application Publication
(10) Pub. No.: US 2026/0231461 A1
(43) Pub. Date: Aug. 6, 2026

(54) SEMICONDUCTOR DEVICE

(71) Applicant: KABUSHIKI KAISHA TOSHIBA, Kawasaki-shi (JP)

(72) Inventors: Ryoma KANEKO, Ota Tokyo (JP); Jumpei TAJIMA, Mitaka Tokyo (JP); Mariko SHIMIZU, Setagaya Tokyo (JP); Shinya NUNOUE, Ichikawa Chiba (JP); Toshiki HIKOSAKA, Kawasaki Kanagawa (JP)

(73) Assignee: KABUSHIKI KAISHA TOSHIBA, Kawasaki-shi (JP)

(21) Appl. No.: 19/417,681

(22) Filed: Dec. 12, 2025

(30) Foreign Application Priority Data
Feb. 5, 2025 (JP) 2025-017897

(51) Int. Cl. H10D 30/47; H10D 62/10; H10D 62/60; H10D 62/82; H10D 64/27

(52) U.S. Cl. CPC H10D 30/475; H10D 30/476; H10D 62/102; H10D 62/124; H10D 62/60; H10D 62/82; H10D 64/513; H10D 64/514; H10D 64/518

(57) ABSTRACT

According to one embodiment, a semiconductor device includes first to third electrodes, a semiconductor member, and a first insulating member. The semiconductor member includes a first semiconductor layer including Alₓ₁Ga₁₋ₓ₁N (0≤x1<1), a second semiconductor layer including Alₓ₂Ga₁₋ₓ₂N (0≤x2<1), and a third semiconductor layer including Alₓ₃Ga₁₋ₓ₃N (x2<x3≤1, x1<x3). A position of a third semiconductor portion of the second semiconductor layer in the first direction is between a position of the first electrode portion in the first direction and a position of the second semiconductor region in the first direction. The third semiconductor portion includes silicon. The first semiconductor layer does not include silicon, or a first semiconductor layer silicon concentration in the first semiconductor layer is lower than a third silicon concentration in the third semiconductor portion.

### CROSS-REFERENCE TO RELATED APPLICATIONS

This application is based upon and claims the benefit of priority from Japanese Patent Application No. 2025-017897, filed on Feb. 5, 2025; the entire contents of which are incorporated herein by reference.

### FIELD

Embodiments described herein relate generally to a semiconductor device.

### BACKGROUND

For example, it is desirable to improve the characteristics of semiconductor devices, such as transistors.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a semiconductor device according to the first embodiment;

FIG. 3 is a schematic cross-sectional view illustrating a semiconductor device according to a second embodiment; and

FIG. 4 is a schematic cross-sectional view illustrating a semiconductor device according to a third embodiment.

### DETAILED DESCRIPTION

According to one embodiment, a semiconductor device includes a first electrode, a second electrode, a third electrode, a semiconductor member, and a first insulating member. A direction from the first electrode to the second electrode is along a first direction. The third electrode includes a first electrode portion. A third electrode position of the first electrode portion in the first direction is between a first electrode position of the first electrode in the first direction and a second electrode position of the second electrode in the first direction. At least a part of the first insulating member is provided between the third electrode and the semiconductor member. The semiconductor member includes a first semiconductor layer including Alₓ₁Ga₁₋ₓ₁N (0≤x1<1), a second semiconductor layer including Alₓ₂Ga₁₋ₓ₂N (0≤x2<1), and a third semiconductor layer including Alₓ₃Ga₁₋ₓ₃N (x2<x3≤1, x1<x3). The first semiconductor layer includes a first partial region, a second partial region, a third partial region, a fourth partial region, and a fifth partial region. A second direction from the first partial region to the first electrode crosses the first direction. A direction from the second partial region to the second electrode is along the second direction. A direction from the third partial region to the first electrode portion is along the second direction. A fourth position of the fourth partial region in the first direction is between a first position of the first partial region in the first direction and a third position of the third partial region in the first direction. A fifth position of the fifth partial region in the first direction is between the third position and a second position of the second partial region in the first direction. The second semiconductor layer includes a first semiconductor portion, a second semiconductor portion, and a third semiconductor portion. At least a part of the first electrode portion is between the first semiconductor portion and the second semiconductor portion in the first direction. The third semiconductor portion is between the first electrode portion and the second semiconductor portion in the first direction. The third semiconductor layer includes a first semiconductor region and a second semiconductor region. The first semiconductor portion is between the fourth partial region and the first semiconductor region in the second direction. The second semiconductor portion is between the fifth partial region and the second semiconductor region in the second direction. A position of the third semiconductor portion in the first direction is between a position of the first electrode portion in the first direction and a position of the second semiconductor region in the first direction. The third semiconductor portion includes silicon. The first semiconductor layer does not include silicon, or a first semiconductor layer silicon concentration in the first semiconductor layer is lower than a third silicon concentration in the third semiconductor portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

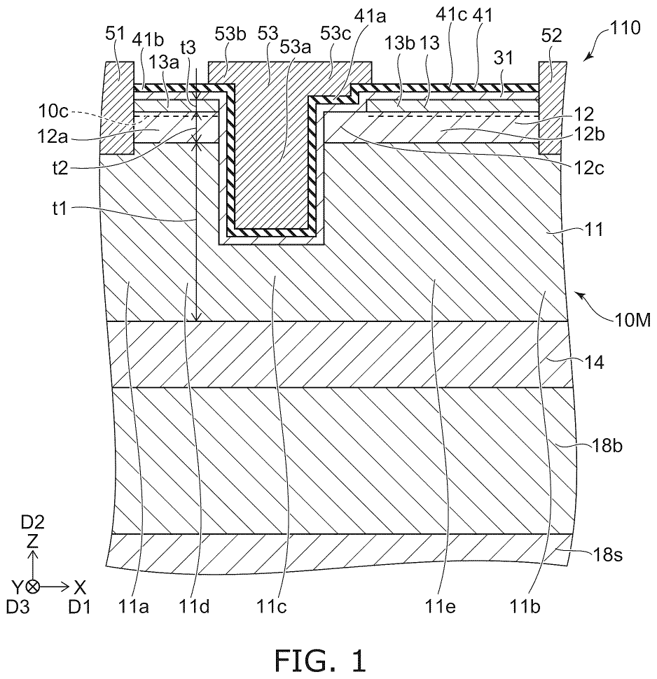

FIG. 1 is a schematic cross-sectional view illustrating a semiconductor device according to a first embodiment. As shown in FIG. 1, a semiconductor device 110 according to the embodiment includes a first electrode 51, a second electrode 52, a third electrode 53, a semiconductor member 10M, and a first insulating member 41.

A direction from the first electrode 51 to the second electrode 52 is along a first direction D1. The first direction D1 is taken as an X-axis direction. One direction perpendicular to the X-axis direction is taken as a Z-axis direction. A direction perpendicular to the X-axis direction and the Z-axis direction is taken as a Y-axis direction.

The third electrode 53 includes a first electrode portion 53a. The position (third electrode position) of the first electrode portion 53a in the first direction D1 is between the position (first electrode position) of the first electrode 51 in the first direction D1 and the position (second electrode position) of the second electrode 52 in the first direction D1.

At least a part of the first insulating member 41 is provided between the third electrode 53 and the semiconductor member 10M. For example, the first insulating member 41 electrically insulates the third electrode 53 and the semiconductor member 10M from each other. The semiconductor member 10M includes a first semiconductor layer 11, a second semiconductor layer 12, and a third semiconductor layer 13. The first semiconductor layer 11 includes Alₓ₁Ga₁₋ₓ₁N (0≤x1<1). The composition ratio x1 may be, for example, 0 or more and 0.05 or less. The first semiconductor layer 11 may include, for example, GaN. The second semiconductor layer 12 includes Alₓ₂Ga₁₋ₓ₂N (0≤x2<1). The composition ratio x2 may be, for example, 0 or more and 0.05 or less. The second semiconductor layer 12 may include, for example, GaN.

The third semiconductor layer 13 includes Alₓ₃Ga₁₋ₓ₃N (x2<x3≤1, x1<x3). The composition ratio x3 may be, for example, 0.15 or more and 0.3 or less. The third semiconductor layer 13 includes, for example, AlGaN.

The first semiconductor layer 11 includes, for example, a first partial region 11a, a second partial region 11b, a third partial region 11c, a fourth partial region 11d, and a fifth partial region 11e. A second direction D2 from the first partial region 11a to the first electrode 51 crosses the first direction D1. The second direction D2 is, for example, the Z-axis direction.

A direction from the second partial region 11b to the second electrode 52 is along the second direction D2. A direction from the third partial region 11c to the first electrode portion 53a is along the second direction D2. The position (fourth position) of the fourth partial region 11d in the first direction D1 is between the position (first position) of the first partial region 11a in the first direction D1 and the position (third position) of the third partial region 11c in the first direction D1. The position (fifth position) of the fifth partial region 11e in the first direction D1 is between the third position and the position (second position) of the second partial region 11b in the first direction D1.

A region overlapping the first electrode 51 in the second direction D2 corresponds to the first partial region 11a. A region overlapping the second electrode 52 in the second direction D2 corresponds to the second partial region 11b. A region overlapping the first electrode portion 53a in the second direction D2 corresponds to the third partial region 11c. The boundaries between the plurality of partial regions described above may be clear or unclear.

The second semiconductor layer 12 includes a first semiconductor portion 12a, a second semiconductor portion 12b, and a third semiconductor portion 12c. At least a part of the first electrode portion 53a is between the first semiconductor portion 12a and the second semiconductor portion 12b in the first direction D1. The third semiconductor portion 12c is between the first electrode portion 53a and the second semiconductor portion 12b in the first direction D1. The position of the third semiconductor portion 12c in the first direction D1 is between the position of the first electrode portion 53a in the first direction D1 and the position of the second semiconductor region 13b in the first direction D1. The third semiconductor portion 12c may be continuous with or in contact with the second semiconductor portion 12b. The third semiconductor portion 12c may be continuous with or in contact with the fifth partial region 11e.

The third semiconductor layer 13 includes a first semiconductor region 13a and a second semiconductor region 13b. The first semiconductor portion 12a is between the fourth partial region 11d and the first semiconductor region 13a in the second direction D2.

The second semiconductor portion 12b is between the fifth partial region 11e and the second semiconductor region 13b in the second direction D2. The second semiconductor region 13b does not overlap the third semiconductor portion 12c in the second direction D2. A region overlapping the second semiconductor region 13b in the second direction D2 corresponds to the second semiconductor portion 12b. A region not overlapping the second semiconductor region 13b in the second direction D2 corresponds to the third semiconductor portion 12c.

For example, the position of the third semiconductor portion 12c in the first direction D1 is between the position of the first electrode portion 53a in the first direction D1 and the position of the second semiconductor region 13b in the first direction D1.

In the embodiment, the third semiconductor portion 12c includes silicon. The first semiconductor layer 11 does not include silicon. Alternatively, the silicon concentration (first semiconductor layer silicon concentration) in the first semiconductor layer 11 is lower than the silicon concentration (third silicon concentration) in the third semiconductor portion 12c.

For example, the first semiconductor layer 11 includes i-GaN. The third semiconductor portion 12c includes, for example, n-type GaN.

The current flowing between the first electrode 51 and the second electrode 52 can be controlled by the potential of the third electrode 53. The potential of the third electrode 53 may be, for example, a potential based on the potential of the first electrode 51. The first electrode 51 functions as, for example, a source electrode. The second electrode 52 functions as, for example, a drain electrode. The third electrode 53 functions as, for example, a gate electrode. The semiconductor device 110 is, for example, a transistor. The third electrode 53 is, for example, a recess-type gate electrode. The third semiconductor portion 12c is provided in the recess end portion.

The second semiconductor layer 12 includes a portion facing the third semiconductor layer 13. A carrier region 10c may be formed in this portion. The carrier region 10c is, for example, a two-dimensional electron gas. The semiconductor device 110 is, for example, a HEMT (High Electron Mobility Transistor).

As described above, in the embodiment, the third semiconductor portion 12c including silicon is provided. Accordingly, a high threshold voltage is obtained. According to the embodiment, a semiconductor device capable of improving the characteristics can be provided.

For example, the short channel effect at the recess end is suppressed by the third semiconductor portion 12c including silicon. For example, good gate controllability is obtained. For example, a lower SS (subthreshold swing) value is obtained. For example, a high-speed switching operation is obtained.

In the embodiment, the entire second semiconductor layer 12 may include silicon. A semiconductor layer including silicon is obtained by a simple process. For example, the silicon concentration (second silicon concentration) in the second semiconductor portion 12b may be higher than the silicon concentration (first semiconductor layer silicon concentration) in the first semiconductor layer 11. The silicon concentration (first silicon concentration) in the first semiconductor portion 12a may be higher than the first semiconductor layer silicon concentration.

The silicon concentration (third silicon concentration) in the third semiconductor portion 12c may be, for example, 1×10¹⁶/cm³ or more and 5×10¹⁷/cm³ or less. The silicon concentration (third silicon concentration) in the third semiconductor portion 12c may be, for example, 5×10¹⁶/cm³ or more and 5×10¹⁷/cm³ or less. The silicon concentration in the second semiconductor layer 12 may be, for example, 1×10¹⁶/cm³ or more and 5×10¹⁷/cm³ or less. The silicon concentration (first semiconductor layer silicon concentration) in the first semiconductor layer 11 may be, for example, less than 1×10¹⁶/cm³. A high threshold voltage is stably obtained.

As shown in FIG. 1, the first insulating member 41 may include a first insulating portion 41a. The third semiconductor portion 12c is between the fifth partial region 11e and the first insulating portion 41a in the second direction D2. The first insulating portion 41a is between the first electrode portion 53a and the second semiconductor region 13b in the first direction D1. In the portion of the first insulating portion 41a, a step may be formed due to the presence or absence of the second semiconductor region 13b.

The first insulating member 41 may further include a second insulating portion 41b and a third insulating portion 41c. At least a part of the first semiconductor region 13a is between the first semiconductor portion 12a and the second insulating portion 41b in the second direction D2. The second semiconductor region 13b is between the second semiconductor portion 12b and the third insulating portion 41c in the second direction D2.

As shown in FIG. 1, the third electrode 53 may further include a third electrode portion 53c. The third semiconductor portion 12c is between the fifth partial region 11e and the third electrode portion 53c in the second direction D2.

The first electrode portion 53a is between the first semiconductor region 13a and the second semiconductor region 13b in the first direction D1.

As shown in FIG. 1, for example, the first electrode portion 53a may be provided between two portions of the first semiconductor layer 11 in the first direction D1. The first electrode portion 53a is between the fourth partial region 11d and the fifth partial region 11e in the first direction D1. A higher threshold voltage is obtained.

As shown in FIG. 1, the semiconductor device 110 may further include a first compound layer 31. The first compound layer 31 includes Al_{z1}Ga_{1-z1}N (0<z1≤1, x3<z1). The composition ratio z1 may be, for example, 0.6 or more and 1 or less. The first compound layer 31 may include, for example, AlN. The first compound layer 31 is between the semiconductor member 10M and the first insulating member 41.

The third semiconductor portion 12c is in contact with the first compound layer 31 or the first insulating member 41 in the first direction D1. The third semiconductor portion 12c is in contact with the first compound layer 31 or the first insulating member 41 in the second direction D2.

For example, the third partial region 11c of the first semiconductor layer 11 may include a portion facing the first compound layer 31 in the first direction D1. The carrier region 10c may be formed in this portion. For example, a high mobility is obtained. For example, a low on-resistance is obtained.

As shown in FIG. 1, the thickness of the first semiconductor layer 11 along the second direction D2 is taken as a first thickness t1. The thickness of the second semiconductor layer 12 along the second direction D2 is taken as a second thickness t2. The first thickness t1 is preferably thicker than the second thickness t2. Stable characteristics are easily obtained.

The thickness of the third semiconductor layer 13 along the second direction D2 is taken as a third thickness t3. The third thickness t3 is preferably thinner than the second thickness t2. Stable characteristics are easily obtained.

In one example, the first thickness t1 may be 300 nm or more and 1000 nm or less. The second thickness t2 may be, for example, 20 nm or more and 100 nm or less. The third thickness t3 may be, for example, 10 nm or more and 50 nm or less.

The third electrode 53 may further include a second electrode portion 53b. At least a part of the first semiconductor portion 12a may be provided between the fourth partial region 11d and the second electrode portion 53b in the second direction D2.

The first electrode 51, the second electrode 52, and the third electrode 53 may extend along a third direction D3. The third direction D3 crosses a plane including the first direction D1 and the second direction D2. The third direction D3 may be, for example, the Y-axis direction.

As shown in FIG. 1, the semiconductor member 10M may include a fourth semiconductor layer 14. The fourth semiconductor layer 14 includes Alₓ₄Ga₁₋ₓ₄N (0≤x4<1, x4<x3). The composition ratio x4 may be 0 or more and 0.05 or less. The fourth semiconductor layer 14 includes, for example, GaN. The first semiconductor layer 11 is between the fourth semiconductor layer 14 and the second semiconductor layer 12 in the second direction D2. The fourth semiconductor layer 14 includes carbon. The first semiconductor layer 11 does not include carbon. Alternatively, the carbon concentration (first carbon concentration) in the first semiconductor layer 11 is lower than the carbon concentration (fourth carbon concentration) in the fourth semiconductor layer 14. For example, a high breakdown voltage is easily obtained with the fourth semiconductor layer 14.

The second semiconductor layer 12 does not include carbon. Alternatively, the carbon concentration (second carbon concentration) in the second semiconductor layer 12 is lower than the first carbon concentration. The second carbon concentration may be, for example, less than 1×10¹⁶/cm³. The first carbon concentration may be, for example, 1×10¹⁶/cm³ or more and less than 5×10¹⁷/cm³.

As shown in FIG. 1, the semiconductor device 110 may include a base 18s and a nitride layer 18b. The first semiconductor layer 11 is between the base 18s and the second semiconductor layer 12. The nitride layer 18b is between the base 18s and the first semiconductor layer 11. The base 18s may include, for example, silicon. The nitride layer 18b may include, for example, Al, Ga, and N. The nitride layer 18b is, for example, a buffer layer.

The first electrode 51 is electrically connected to the first semiconductor portion 12a. The second electrode 52 is electrically connected to the second semiconductor portion 12b.

The distance between the first electrode 51 and the third electrode 53 along the first direction D1 may be shorter than the distance between the third electrode 53 and the second electrode 52 along the first direction D1. Stable characteristics are obtained.

The third semiconductor portion 12c may be formed by, for example, selective growth or ion implantation.

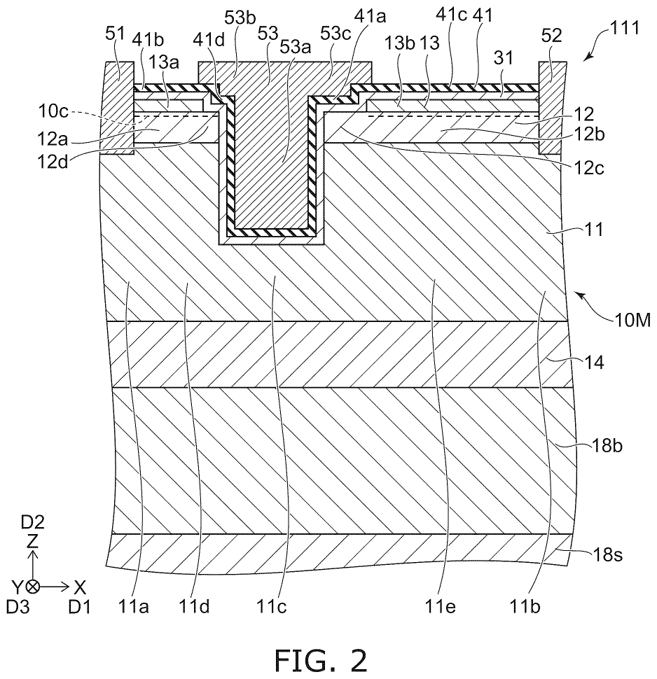

FIG. 2 is a schematic cross-sectional view illustrating a semiconductor device according to the first embodiment.

As shown in FIG. 2, in a semiconductor device 111 according to the embodiment, the first semiconductor region 13a does not overlap a part of the first semiconductor portion 12a. The configuration of the semiconductor device 111 may be otherwise similar to the configuration of the semiconductor device 110.

In the semiconductor device 111, the second semiconductor layer 12 further includes a fourth semiconductor portion 12d. The fourth semiconductor portion 12d is between the first semiconductor portion 12a and the first electrode portion 53a in the first direction D1. The first semiconductor region 13a does not overlap the fourth semiconductor portion 12d in the second direction D2. The first semiconductor region 13a overlaps the first semiconductor portion 12a in the second direction D2.

The fourth semiconductor portion 12d includes silicon. The silicon concentration (first semiconductor layer silicon concentration) in the first semiconductor layer 11 is lower than the silicon concentration (fourth silicon concentration) in the fourth semiconductor portion 12d.

Since the first semiconductor region 13a does not overlap the fourth semiconductor portion 12d including silicon, a high threshold voltage is stably obtained.

The first insulating member 41 may include a fourth insulating portion 41d. The fourth semiconductor portion 12d is between the fourth partial region 11d and the fourth insulating portion 41d in the second direction D2. The fourth insulating portion 41d is between the first semiconductor region 13a and the first electrode portion 53a in the first direction D1.

The third electrode 53 may further include the second electrode portion 53b. The fourth semiconductor portion 12d is between the fourth partial region 11d and the second electrode portion 53b in the second direction D2. The fourth semiconductor portion 12d is in contact with the first compound layer 31 or the first insulating member 41 in the first direction D1.

### Second Embodiment

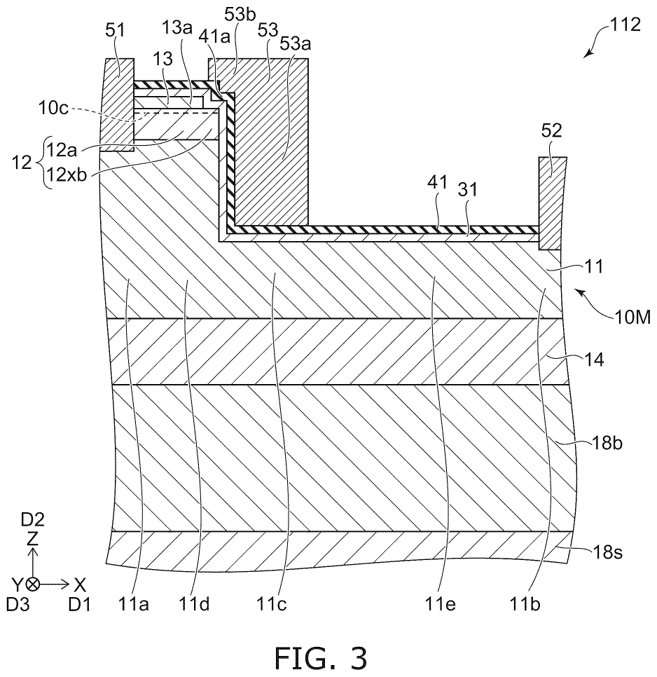

FIG. 3 is a schematic cross-sectional view illustrating a semiconductor device according to a second embodiment.

As shown in FIG. 3, a semiconductor device 112 according to the embodiment includes the first electrode 51, the second electrode 52, the third electrode 53, the semiconductor member 10M, and the first insulating member 41. In the semiconductor device 112, the third semiconductor layer 13 includes the first semiconductor region 13a and does not include the second semiconductor region 13b. To the configuration of the semiconductor device 112 other than this, the configuration described in relation to the semiconductor device 110 or the semiconductor device 111 may be applied.

In the semiconductor device 112, a direction from the first electrode 51 to the second electrode 52 is along the first direction D1. The position (third electrode position) of the first electrode portion 53a in the first direction D1 is between the position (first electrode position) of the first electrode 51 in the first direction D1 and the position (second electrode position) of the second electrode 52 in the first direction D1.

At least a part of the first insulating member 41 is provided between the third electrode 53 and the semiconductor member 10M.

The semiconductor member 10M includes the first semiconductor layer 11 including Alₓ₁Ga₁₋ₓ₁N (0≤x1<1), the second semiconductor layer 12 including Alₓ₂Ga₁₋ₓ₂N (0≤x2<1), and the third semiconductor layer 13 including Alₓ₃Ga₁₋ₓ₃N (x2<x3≤1, x1<x3).

The first semiconductor layer 11 includes the first partial region 11a, the second partial region 11b, the third partial region 11c, the fourth partial region 11d, and the fifth partial region 11e. The second direction D2 from the first partial region 11a to the first electrode 51 crosses the first direction D1. A direction from the second partial region 11b to the second electrode 52 is along the second direction D2. A direction from the third partial region 11c to the first electrode portion 53a is along the second direction D2.

The fourth position of the fourth partial region 11d in the first direction D1 is between the first position of the first partial region 11a in the first direction D1 and the third position of the third partial region 11c in the first direction D1. The fifth position of the fifth partial region 11e in the first direction D1 is between the third position and the second position of the second partial region 11b in the first direction D1.

The second semiconductor layer 12 includes the first semiconductor portion 12a and a second semiconductor portion 12xb. The second semiconductor portion 12xb is between the first semiconductor portion 12a and the first electrode portion 53a in the first direction D1. The first semiconductor portion 12a is between the fourth partial region 11d and the third semiconductor layer 13 in the second direction D2. The third semiconductor layer 13 does not overlap the second semiconductor portion 12xb in the second direction D2.

The second semiconductor portion 12xb includes silicon. The first semiconductor layer 11 does not include silicon. Alternatively, the silicon concentration (first semiconductor layer silicon concentration) in the first semiconductor layer 11 is lower than the silicon concentration (second silicon concentration) in the second semiconductor portion 12xb.

A high threshold voltage is also obtained in the semiconductor device 112. A semiconductor device capable of improving the characteristics can be provided.

In the semiconductor device 112, the silicon concentration (first silicon concentration) in the first semiconductor portion 12a may be higher than the first semiconductor layer silicon concentration.

The first insulating member 41 may include the first insulating portion 41a. The second semiconductor portion 12xb is between the fourth partial region 11d and the first insulating portion 41a in the second direction D2. The first insulating portion 41a is between the third semiconductor layer 13 and the first electrode portion 53a in the first direction D1.

In the first embodiment and the second embodiment, the first semiconductor layer 11 does not include a p-type impurity. Alternatively, the concentration of the p-type impurity in the first semiconductor layer 11 is less than 1×10¹⁷cm⁻³. Since the p-type impurity is not provided, for example, a high crystallinity is obtained. For example, a high mobility is obtained. The p-type impurity includes, for example, at least one selected from the group consisting of Mg, Zn, and Be.

In the semiconductor member 10M, the structure of each of the plurality of semiconductor layers may be formed by, for example, selectively removing a film that serves as the semiconductor layer. The structure of each of the plurality of semiconductor layers may be formed by, for example, selectively growing a film that serves as the semiconductor layer.

### Third Embodiment

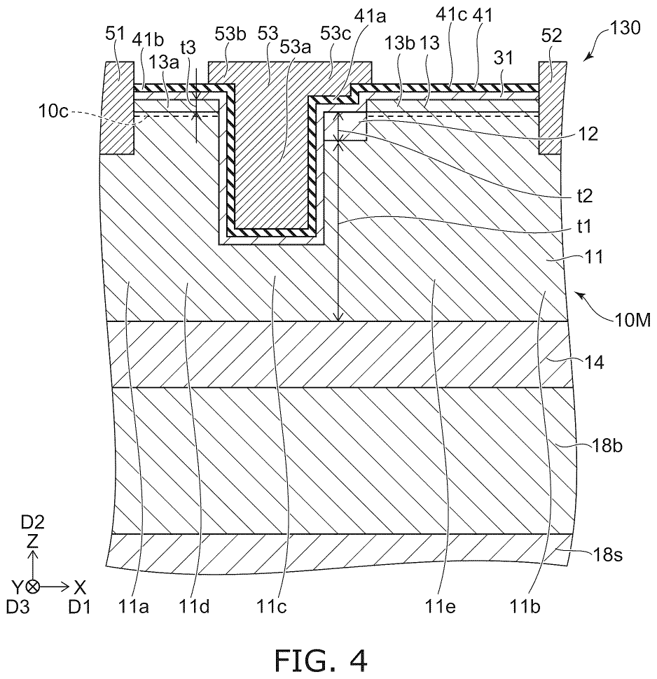

FIG. 4 is a schematic cross-sectional view illustrating a semiconductor device according to a third embodiment.

As shown in FIG. 4, a semiconductor device 130 according to the embodiment includes the first electrode 51, the second electrode 52, the third electrode 53, the semiconductor member 10M, and the first insulating member 41. A direction from the first electrode 51 to the second electrode 52 is along the first direction D1. The third electrode 53 includes the first electrode portion 53a. The third electrode position of the first electrode portion 53a in the first direction D1 is between the first electrode position of the first electrode 51 in the first direction D1 and the second electrode position of the second electrode 52 in the first direction D1. At least a part of the first insulating member 41 is provided between the third electrode 53 and the semiconductor member 10M.

The semiconductor member 10M includes the first semiconductor layer 11 including Alₓ₁Ga₁₋ₓ₁N (0≤x1<1), the second semiconductor layer 12 including Alₓ₂Ga₁₋ₓ₂N (0≤x2<1), and the third semiconductor layer 13 including Alₓ₃Ga₁₋ₓ₃N (x2<x3≤1, x1<x3).

The first semiconductor layer 11 includes the first partial region 11a, the second partial region 11b, the third partial region 11c, the fourth partial region 11d, and the fifth partial region 11e. The second direction D2 from the first partial region 11a to the first electrode 51 crosses the first direction D1. A direction from the second partial region 11b to the second electrode 52 is along the second direction D2. A direction from the third partial region 11c to the first electrode portion 53a is along the second direction D2.

The fourth position of the fourth partial region 11d in the first direction D1 is between the first position of the first partial region 11a in the first direction D1 and the third position of the third partial region 11c in the first direction D1. The fifth position of the fifth partial region 11e in the first direction D1 is between the third position and the second position of the second partial region 11b in the first direction D1.

The third semiconductor layer 13 includes the first semiconductor region 13a and the second semiconductor region 13b. A direction from the fourth partial region 11d to the first semiconductor region 13a is along the second direction D2. A direction from the fifth partial region 11e to the second semiconductor region 13b is along the second direction D2. At least a part of the first electrode portion 53a is between the first semiconductor region 13a and the second semiconductor region 13b in the first direction D1.

The second semiconductor layer 12 is between the first electrode portion 53a and a part of the fourth partial region 11d in the first direction D1. The position of the second semiconductor layer 12 in the first direction D1 is between the position of the first electrode portion 53a in the first direction D1 and the position of the second semiconductor region 13b in the first direction D1. For example, the second semiconductor layer 12 does not overlap the second semiconductor region 13b in the second direction D2.

The second semiconductor layer 12 includes silicon. The first semiconductor layer 11 does not include silicon. Alternatively, the silicon concentration (first semiconductor layer silicon concentration) in the first semiconductor layer 11 is lower than the silicon concentration in the second semiconductor layer 12.

In the semiconductor device 130, the second semiconductor layer 12 is provided at the recess end. Accordingly, the channel mobility increases. For example, a lower on-resistance is obtained. The second semiconductor layer 12 may be formed by, for example, selective growth or ion implantation.

In the embodiment, at least one of the first electrode 51 or the second electrode 52 may include a metal. The metal may include at least one selected from the group consisting of Al, Au, Ag, Cu, Ti, and Ni. The third electrode 53 may include at least one selected from the group consisting of metal and silicon (for example, polysilicon).

The first insulating member 41 may include, for example, a first element and a second element. The first element includes, for example, at least one selected from the group consisting of Si, Al, and Hf. The second element includes, for example, oxygen. The second element may include nitrogen.

In the embodiment, information regarding, for example, the shapes of the semiconductor layers are obtained from, for example, an electron microscope image. Information regarding the compositions and the element concentrations is obtained by, for example, EDX (Energy Dispersive X-ray Spectroscopy) or SIMS (Secondary Ion Mass Spectrometry). Information regarding the compositions may be obtained by, for example, reciprocal space mapping.

The embodiments may include the following technical proposals.

### Technical Proposal 1

A semiconductor device comprising:
a first electrode;
a second electrode, a direction from the first electrode to the second electrode being along a first direction;
a third electrode including a first electrode portion, a third electrode position of the first electrode portion in the first direction being between a first electrode position of the first electrode in the first direction and a second electrode position of the second electrode in the first direction;
a semiconductor member; and
a first insulating member, at least a part of the first insulating member being provided between the third electrode and the semiconductor member,
the semiconductor member including
   a first semiconductor layer including Alₓ₁Ga₁₋ₓ₁N (0≤x1<1),
   a second semiconductor layer including Alₓ₂Ga₁₋ₓ₂N (0≤x2<1), and
   a third semiconductor layer including Alₓ₃Ga₁₋ₓ₃N (x2<x3≤1, x1<x3),
the first semiconductor layer including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the first electrode portion being along the second direction,
a fourth position of the fourth partial region in the first direction being between a first position of the first partial region in the first direction and a third position of the third partial region in the first direction,
a fifth position of the fifth partial region in the first direction being between the third position and a second position of the second partial region in the first direction,
the second semiconductor layer including a first semiconductor portion, a second semiconductor portion, and a third semiconductor portion,
at least a part of the first electrode portion being between the first semiconductor portion and the second semiconductor portion in the first direction,
the third semiconductor portion being between the first electrode portion and the second semiconductor portion in the first direction,
the third semiconductor layer including a first semiconductor region and a second semiconductor region,
the first semiconductor portion being between the fourth partial region and the first semiconductor region in the second direction,
the second semiconductor portion being between the fifth partial region and the second semiconductor region in the second direction,
a position of the third semiconductor portion in the first direction being between a position of the first electrode portion in the first direction and a position of the second semiconductor region in the first direction,
the third semiconductor portion including silicon,
the first semiconductor layer not including silicon, or a first semiconductor layer silicon concentration in the first semiconductor layer being lower than a third silicon concentration in the third semiconductor portion.

### Technical Proposal 2

The semiconductor device according to Technical proposal 1, wherein the second semiconductor region does not overlap the third semiconductor portion in the second direction.

### Technical Proposal 3

The semiconductor device according to Technical proposal 1 or 2, wherein a second silicon concentration in the second semiconductor portion is higher than the first semiconductor layer silicon concentration.

### Technical Proposal 4

The semiconductor device according to any one of Technical proposals 1 to 3, wherein
the first insulating member includes a first insulating portion,
the third semiconductor portion is between the fifth partial region and the first insulating portion in the second direction, and
the first insulating portion is between the first electrode portion and the second semiconductor region in the first direction.

### Technical Proposal 5

The semiconductor device according to any one of Technical proposals 1 to 4, further comprising:
a first compound layer including Al_{z1}Ga_{1-z1}N (0<z1≤1, x3<z1),
the first compound layer being between the semiconductor member and the first insulating member.

### Technical Proposal 6

The semiconductor device according to any one of Technical proposals 1 to 5, wherein the third silicon concentration is not less than 1×10¹⁶/cm³ and not more than 5×10¹⁷/cm³.

### Technical Proposal 7

The semiconductor device according to any one of Technical proposals 1 to 6, wherein
the second semiconductor layer further includes a fourth semiconductor portion,
the fourth semiconductor portion is between the first semiconductor portion and the first electrode portion in the first direction,
the first semiconductor region does not overlap the fourth semiconductor portion in the second direction,
the fourth semiconductor portion includes silicon, and
the first semiconductor layer silicon concentration is lower than a fourth silicon concentration in the fourth semiconductor portion.

### Technical Proposal 8

The semiconductor device according to Technical proposal 7, wherein
the first insulating member includes a fourth insulating portion,
the fourth semiconductor portion is between the fourth partial region and the fourth insulating portion in the second direction, and
the fourth insulating portion is between the first semiconductor region and the first electrode portion in the first direction.

### Technical Proposal 9

The semiconductor device according to Technical proposal 7 or 8, wherein
the third electrode further includes a second electrode portion, and
the fourth semiconductor portion is between the fourth partial region and the second electrode portion in the second direction.

### Technical Proposal 10

The semiconductor device according to any one of Technical proposals 1 to 8, wherein a first thickness of the first semiconductor layer along the second direction is thicker than a second thickness of the second semiconductor layer along the second direction.

### Technical Proposal 11

The semiconductor device according to Technical proposal 10, wherein
the first thickness is not less than 300 nm and not more than 1000 nm, and
the second thickness is not less than 20 nm and not more than 100 nm.

### Technical Proposal 12

The semiconductor device according to Technical proposal 10 or 11, wherein a third thickness of the third semiconductor layer along the second direction is thinner than the second thickness.

### Technical Proposal 13

The semiconductor device according to any one of Technical proposals 1 to 12, wherein
the semiconductor member further includes a fourth semiconductor layer including Alₓ₄Ga₁₋ₓ₄N (0≤x4<1, x4<x3),
the first semiconductor layer is between the fourth semiconductor layer and the second semiconductor layer in the second direction,
the fourth semiconductor layer includes carbon, and
the first semiconductor layer does not include carbon, or a first carbon concentration in the first semiconductor layer is lower than a fourth carbon concentration in the fourth semiconductor layer.

### Technical Proposal 14

The semiconductor device according to any one of Technical proposals 1 to 13, wherein
the third electrode further includes a third electrode portion, and
the third semiconductor portion is between the fifth partial region and the third electrode portion in the second direction.

### Technical Proposal 15

The semiconductor device according to any one of Technical proposals 1 to 14, wherein the first electrode portion is between the first semiconductor region and the second semiconductor region in the first direction.

### Technical Proposal 16

A semiconductor device comprising:
a first electrode;
a second electrode, a direction from the first electrode to the second electrode being along a first direction;
a third electrode including a first electrode portion, a third electrode position of the first electrode portion in the first direction being between a first electrode position of the first electrode in the first direction and a second electrode position of the second electrode in the first direction;
a semiconductor member; and
a first insulating member, at least a part of the first insulating member being provided between the third electrode and the semiconductor member,
the semiconductor member including
   a first semiconductor layer including Alₓ₁Ga₁₋ₓ₁N (0≤x1<1),
   a second semiconductor layer including Alₓ₂Ga₁₋ₓ₂N (0≤x2<1), and
   a third semiconductor layer including Alₓ₃Ga₁₋ₓ₃N (x2<x3≤1, x1<x3),
the first semiconductor layer including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the first electrode portion being along the second direction,
a fourth position of the fourth partial region in the first direction being between a first position of the first partial region in the first direction and a third position of the third partial region in the first direction,
a fifth position of the fifth partial region in the first direction being between the third position and a second position of the second partial region in the first direction,
the second semiconductor layer including a first semiconductor portion and a second semiconductor portion,
the second semiconductor portion being between the first semiconductor portion and the first electrode portion in the first direction,
the first semiconductor portion being between the fourth partial region and the third semiconductor layer in the second direction,
the third semiconductor layer not overlapping the second semiconductor portion in the second direction,
the second semiconductor portion including silicon,
the first semiconductor layer not including silicon, or a first semiconductor layer silicon concentration in the first semiconductor layer being lower than a second silicon concentration in the second semiconductor portion.

### Technical Proposal 17

The semiconductor device according to Technical proposal 16, wherein a first silicon concentration in the first semiconductor portion is higher than the first semiconductor layer silicon concentration.

### Technical Proposal 18

A semiconductor device comprising:
a first electrode;
a second electrode, a direction from the first electrode to the second electrode being along a first direction;
a third electrode including a first electrode portion, a third electrode position of the first electrode portion in the first direction being between a first electrode position of the first electrode in the first direction and a second electrode position of the second electrode in the first direction;
a semiconductor member; and
a first insulating member,
at least a part of the first insulating member being provided between the third electrode and the semiconductor member,
the semiconductor member including
   a first semiconductor layer including Alₓ₁Ga₁₋ₓ₁N (0≤x1<1),
   a second semiconductor layer including Alₓ₂Ga₁₋ₓ₂N (0≤x2<1), and
   a third semiconductor layer including Alₓ₃Ga₁₋ₓ₃N (x2<x3≤1, x1<x3),
the first semiconductor layer including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the first electrode portion being along the second direction,
a fourth position of the fourth partial region in the first direction being between a first position of the first partial region in the first direction and a third position of the third partial region in the first direction,
a fifth position of the fifth partial region in the first direction being between the third position and a second position of the second partial region in the first direction,
the third semiconductor layer including a first semiconductor region and a second semiconductor region,
a direction from the fourth partial region to the first semiconductor region being along the second direction,
a direction from the fifth partial region to the second semiconductor region being along the second direction,
at least a part of the first electrode portion being between the first semiconductor region and the second semiconductor region in the first direction,
the second semiconductor layer being between the first electrode portion and a part of the fourth partial region in the first direction,
a position of the second semiconductor layer in the first direction being between a position of the first electrode portion in the first direction and a position of the second semiconductor region in the first direction,
the second semiconductor layer including silicon,
the first semiconductor layer not including silicon, or a first semiconductor layer silicon concentration in the first semiconductor layer being lower than a silicon concentration in the second semiconductor layer.

### Technical Proposal 19

The semiconductor device according to any one of Technical proposals 1 to 18, wherein
the first semiconductor layer does not include a p-type impurity, or
a concentration of the p-type impurity in the first semiconductor layer is less than 1×10¹⁷cm⁻³.

### Technical Proposal 20

The semiconductor device according to Technical proposal 19, wherein the p-type impurity includes at least one selected from the group consisting of Mg, Zn, and Be.

According to the embodiment, a semiconductor device capable of improving the characteristics is provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor layers, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode, a direction from the first electrode to the second electrode being along a first direction;
a third electrode including a first electrode portion, a third electrode position of the first electrode portion in the first direction being between a first electrode position of the first electrode in the first direction and a second electrode position of the second electrode in the first direction;
a semiconductor member; and
a first insulating member,
at least a part of the first insulating member being provided between the third electrode and the semiconductor member,
the semiconductor member including
a first semiconductor layer including Alₓ₁Ga₁₋ₓ₁N (0≤x1<1),
a second semiconductor layer including Alₓ₂Ga₁₋ₓ₂N (0×x2<1), and
a third semiconductor layer including Alₓ₃Ga₁₋ₓ₃N (x2<x3×1, x1<x3),
the first semiconductor layer including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the first electrode portion being along the second direction,
a fourth position of the fourth partial region in the first direction being between a first position of the first partial region in the first direction and a third position of the third partial region in the first direction,
a fifth position of the fifth partial region in the first direction being between the third position and a second position of the second partial region in the first direction,
the second semiconductor layer including a first semiconductor portion, a second semiconductor portion, and a third semiconductor portion,
at least a part of the first electrode portion being between the first semiconductor portion and the second semiconductor portion in the first direction,
the third semiconductor portion being between the first electrode portion and the second semiconductor portion in the first direction,
the third semiconductor layer including a first semiconductor region and a second semiconductor region,
the first semiconductor portion being between the fourth partial region and the first semiconductor region in the second direction,
the second semiconductor portion being between the fifth partial region and the second semiconductor region in the second direction,
a position of the third semiconductor portion in the first direction being between a position of the first electrode portion in the first direction and a position of the second semiconductor region in the first direction,
the third semiconductor portion including silicon,
the first semiconductor layer not including silicon, or a first semiconductor layer silicon concentration in the first semiconductor layer being lower than a third silicon concentration in the third semiconductor portion.

2. The semiconductor device according to claim 1, wherein the second semiconductor region does not overlap the third semiconductor portion in the second direction.

3. The semiconductor device according to claim 1, wherein a second silicon concentration in the second semiconductor portion is higher than the first semiconductor layer silicon concentration.

4. The semiconductor device according to claim 1, wherein
the first insulating member includes a first insulating portion,
the third semiconductor portion is between the fifth partial region and the first insulating portion in the second direction, and
the first insulating portion is between the first electrode portion and the second semiconductor region in the first direction.

5. The semiconductor device according to claim 1, further comprising:
a first compound layer including Al_{z1}Ga_{1-z1}N (0<z1≤1, x3<z1),
the first compound layer being between the semiconductor member and the first insulating member.

6. The semiconductor device according to claim 1, wherein the third silicon concentration is not less than 1×10¹⁶/cm³ and not more than 5×10¹⁷/cm³.

7. The semiconductor device according to claim 1, wherein
the second semiconductor layer further includes a fourth semiconductor portion,
the fourth semiconductor portion is between the first semiconductor portion and the first electrode portion in the first direction,
the first semiconductor region does not overlap the fourth semiconductor portion in the second direction,
the fourth semiconductor portion includes silicon, and
the first semiconductor layer silicon concentration is lower than a fourth silicon concentration in the fourth semiconductor portion.

8. The semiconductor device according to claim 7, wherein
the first insulating member includes a fourth insulating portion,
the fourth semiconductor portion is between the fourth partial region and the fourth insulating portion in the second direction, and
the fourth insulating portion is between the first semiconductor region and the first electrode portion in the first direction.

9. The semiconductor device according to claim 7, wherein
the third electrode further includes a second electrode portion, and
the fourth semiconductor portion is between the fourth partial region and the second electrode portion in the second direction.

10. The semiconductor device according to claim 1, wherein a first thickness of the first semiconductor layer along the second direction is thicker than a second thickness of the second semiconductor layer along the second direction.

11. The semiconductor device according to claim 10, wherein
the first thickness is not less than 300 nm and not more than 1000 nm, and the second thickness is not less than 20 nm and not more than 100 nm.

12. The semiconductor device according to claim 10, wherein a third thickness of the third semiconductor layer along the second direction is thinner than the second thickness.

13. The semiconductor device according to claim 1, wherein
the semiconductor member further includes a fourth semiconductor layer including Alₓ₄Ga₁₋ₓ₄N (0≤x4<1, x4<x3),
the first semiconductor layer is between the fourth semiconductor layer and the second semiconductor layer in the second direction,
the fourth semiconductor layer includes carbon, and
the first semiconductor layer does not include carbon, or a first carbon concentration in the first semiconductor layer is lower than a fourth carbon concentration in the fourth semiconductor layer.

14. The semiconductor device according to claim 1, wherein
the third electrode further includes a third electrode portion, and
the third semiconductor portion is between the fifth partial region and the third electrode portion in the second direction.

15. The semiconductor device according to claim 1, wherein the first electrode portion is between the first semiconductor region and the second semiconductor region in the first direction.

16. A semiconductor device comprising:
a first electrode;
a second electrode, a direction from the first electrode to the second electrode being along a first direction;
a third electrode including a first electrode portion, a third electrode position of the first electrode portion in the first direction being between a first electrode position of the first electrode in the first direction and a second electrode position of the second electrode in the first direction;
a semiconductor member; and
a first insulating member, at least a part of the first insulating member being provided between the third electrode and the semiconductor member,
the semiconductor member including
a first semiconductor layer including Alₓ₁Ga₁₋ₓ₁N (0≤x1<1),
a second semiconductor layer including Alₓ₂Ga₁₋ₓ₂N (0≤x2<1), and
a third semiconductor layer including Alₓ₃Ga₁₋ₓ₃N (x2<x3≤1, x1<x3),
the first semiconductor layer including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the first electrode portion being along the second direction,
a fourth position of the fourth partial region in the first direction being between a first position of the first partial region in the first direction and a third position of the third partial region in the first direction,
a fifth position of the fifth partial region in the first direction being between the third position and a second position of the second partial region in the first direction,
the second semiconductor layer including a first semiconductor portion and a second semiconductor portion,
the second semiconductor portion being between the first semiconductor portion and the first electrode portion in the first direction,
the first semiconductor portion being between the fourth partial region and the third semiconductor layer in the second direction,
the third semiconductor layer not overlapping the second semiconductor portion in the second direction,
the second semiconductor portion including silicon,
the first semiconductor layer not including silicon, or a first semiconductor layer silicon concentration in the first semiconductor layer being lower than a second silicon concentration in the second semiconductor portion.

17. The semiconductor device according to claim 16, wherein a first silicon concentration in the first semiconductor portion is higher than the first semiconductor layer silicon concentration.

18. A semiconductor device comprising:
a first electrode;
a second electrode, a direction from the first electrode to the second electrode being along a first direction;
a third electrode including a first electrode portion, a third electrode position of the first electrode portion in the first direction being between a first electrode position of the first electrode in the first direction and a second electrode position of the second electrode in the first direction;
a semiconductor member; and
a first insulating member,
at least a part of the first insulating member being provided between the third electrode and the semiconductor member,
the semiconductor member including
a first semiconductor layer including Alₓ₁Ga₁₋ₓ₁N (0≤x1<1),
a second semiconductor layer including Alₓ₂Ga₁₋ₓ₂N (0≤x2<1), and
a third semiconductor layer including Alₓ₃Ga₁₋ₓ₃N (x2<x3≤1, x1<x3),
the first semiconductor layer including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the first electrode portion being along the second direction,
a fourth position of the fourth partial region in the first direction being between a first position of the first partial region in the first direction and a third position of the third partial region in the first direction,
a fifth position of the fifth partial region in the first direction being between the third position and a second position of the second partial region in the first direction,
the third semiconductor layer including a first semiconductor region and a second semiconductor region,
a direction from the fourth partial region to the first semiconductor region being along the second direction,
a direction from the fifth partial region to the second semiconductor region being along the second direction,
at least a part of the first electrode portion being between the first semiconductor region and the second semiconductor region in the first direction,
the second semiconductor layer being between the first electrode portion and a part of the fourth partial region in the first direction,
a position of the second semiconductor layer in the first direction being between a position of the first electrode portion in the first direction and a position of the second semiconductor region in the first direction,
the second semiconductor layer including silicon,
the first semiconductor layer not including silicon, or a first semiconductor layer silicon concentration in the first semiconductor layer being lower than a silicon concentration in the second semiconductor layer.

19. The semiconductor device according to claim 1, wherein
the first semiconductor layer does not include a p-type impurity, or
a concentration of the p-type impurity in the first semiconductor layer is less than 1×10¹⁷cm⁻³.

20. The semiconductor device according to claim 19, wherein the p-type impurity includes at least one selected from the group consisting of Mg, Zn, and Be.
